(19) United States
(12) Patent Application Publication
(10) Pub. No.: US 2026/0353771 A1
(43) Pub. Date: Nov. 5, 2026

(54) GATE ALL AROUND (GAA) LOGIC DEVICE INCLUDING A RESONANT TUNNELLING DIODE (RTD) WITH SUPERLATTICE BARRIER LAYERS AND RELATED METHODS

(71) Applicant: Atomera Incorporated, Los Gatos, CA (US)

(72) Inventor: HIDEKI TAKEUCHI, San Jose, CA (US)

(21) Appl. No.: 19/666,464

(22) Filed: May 4, 2026

Related U.S. Application Data
(60) Provisional application No. 63/798,936, filed on May 2, 2025.

(51) Int. Cl. H10D 84/80; H10D 8/75; H10D 30/00; H10D 62/10; H10D 62/17; H10D 62/83; H10D 84/01; H10W 10/00; H10W 10/17

(52) U.S. Cl. CPC H10D 84/811; H10D 8/755; H10D 30/502; H10D 62/371; H10D 84/0109; H10W 10/014; H10W 10/17; H10D 62/121; H10D 62/83

(57) ABSTRACT

Resonant tunnelling diodes (RTDs) have intriguing properties which make them a primary nanoelectronic device for both analogue and digital applications. We propose two different types of RTD-based cells for the cellular neural network (CNN) which exhibit superior performance in terms of complexity, functionality, or processing speed compared to standard cells. In the first cell model, the resistor of the standard cell is replaced by an RTD, which results in a more compact and versatile cell which requires neither self-feedback nor a non-linear output function, and allows three stable equilibrium points. If a resonant tunnelling transistor (RTT) is used instead of the RTD, the dynamics can be controlled through its gate voltage as an additional network parameter. In a majority of CNN applications, bistable cells are sufficient. Utilizing RTD-based bistable logic elements to store the state of the cell, switching occurs almost instantaneously as virtually no charge transfer is necessary, and it is possible to implement non-linear connections in a straightforward manner. Hence, it turns out that RTD-based CNNs are tailor-made for the implementation of extremely fast bipolar operations and non-linear templates. The ideas presented in this paper may also be beneficially applied to other types of circuits and systems such as A/D converters or sigma-delta modulators. Copyright @ 2001 John Wiley & Sons, Ltd.

### RELATED APPLICATIONS

This application claims the benefit of U.S. App. No. 63/798, 936 filed May 2, 2025, which is hereby incorporated herein in its entirety by reference.

### TECHNICAL FIELD

The present disclosure related to semiconductor devices, and more particularly, to semiconductor devices includes resonant tunneling diodes (RTDs) and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices.

Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si-Ge short period superlattice with higher mobility achieved by reducing alloy scattering in the superlattice. Along these lines, U.S. Patent No. 5, 683, 934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region includes alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A semiconductor device may include a semiconductor substrate and a resonant tunneling diode (RTD) above the semiconductor substrate. The RTD may include a first semiconductor electrode, a first superlattice layer on the first semiconductor electrode, a single crystal semiconductor tunneling layer on the first superlattice layer, a second superlattice layer on the single crystal semiconductor tunneling layer, and a second semiconductor electrode on the second superlattice layer. The semiconductor device may further include a gate all around (GAA) transistor on the semiconductor substrate laterally spaced apart from the RTD and electrically coupled thereto. Each of the first and second superlattice layers may include a plurality of stacked groups of layers, with each group of layers including a plurality of stacked base semiconductor monolayers defining a base semiconductor portion and at least one non-semiconductor monolayer constrained within a crystal lattice of adjacent base semiconductor portions.

In an example implementation, the GAA transistor may include an alternating stack of gate layers and semiconductor nanosheet layers, and source and drain regions on opposite sides of the stack defining a channel through the semiconductor nanosheet layers. By way of example, the gate layers may comprise high K metal gate (HKMG) layers. Also by way of example, the first and second semiconductors electrodes may comprise a single crystal semiconductor material, such as single crystal silicon.

In some embodiments, the semiconductor device may further include a punch through stop (PTS) dopant region in the semiconductor substrate beneath the GAA transistor. The semiconductor device may also include a shallow trench isolation (STI) region between the RTD and GAA transistor. By way of example, the base semiconductor may comprises silicon, and the at least one non-semiconductor monolayer may comprise oxygen.

A related method for making a semiconductor device may include forming a resonant tunneling diode (RTD) above a semiconductor substrate by forming a first superlattice layer on a first semiconductor electrode, forming a single crystal semiconductor tunneling layer on the first superlattice layer, forming a second superlattice layer on the single crystal semiconductor tunneling layer, and forming a second semiconductor electrode on the second superlattice layer. The method may further include forming a gate all around (GAA) transistor on the semiconductor substrate laterally spaced apart from the RTD and electrically coupled thereto. Each of the first and second superlattice layers may be similar to those briefly described above.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a plan view of an example trench resonant tunneling diode (RTD) device formed within a semiconductor substrate beneath a CMOS layer, and a cross-sectional view taken along line A-A′ of the plan view, in accordance with an example embodiment.

FIG. 5A is a diagram illustrating an example layout of a cellular neural network (CNN) circuit implemented using MOBILE (monostable-bistable transition logic element) circuits with horizontal JFETs and RTDs, in accordance with an example embodiment.

FIG. 5B is a circuit schematic of an example MOBILE circuit illustrating the series connection of a JFET and RTD pair, along with an example one-dimensional chain of CNN cells, in accordance with an example embodiment.

FIG. 6 is a diagram illustrating an example Epi Damascene process flow for fabricating a trench RTD in accordance with an example embodiment.

FIG. 7 is a schematic illustration of example 3D stacking of MOBILE circuits beneath a CMOS logic layer in accordance with an example embodiment.

FIG. 8 is a cross-sectional view and associated band diagram of an example planar RTD structure using silicon dioxide barrier layers and a silicon tunneling layer with N+ polysilicon electrodes, in accordance with an example embodiment.

FIG. 9 is a process flow diagram, plan view layout, and device cross-sections illustrating an example implementation of the RTD of FIG. 8 into a standard RFSOI process flow, in accordance with an example embodiment.

FIG. 10 is a plan view and A-A′ and B-B′ cross-sectional views of an example saddle FinFET DRAM cell starting structure for RTD insertion, in accordance with an example embodiment.

FIG. 11 is a cross-sectional view illustrating example oxide CVD, BLC block patterning, MST/SiGe/Si selective epitaxial growth, SiGe lateral etch, and radial oxidation/poly-Si CVD process steps for oxide barrier RTD insertion into a DRAM cell, in accordance with an example embodiment.

FIG. 12 is a cross-sectional view and plan view illustrating example RTD lithography/etch, radial oxidation, and SiN sidewall spacer formation steps, in accordance with an example embodiment.

FIG. 13 is a plan view and cross-sectional view illustrating example oxide CVD/CMP and bit line and RTD reference voltage contact formation steps, in accordance with an example embodiment.

FIG. 14 is a plan view and cross-sectional view illustrating example storage node contact and poly-Si cell plate formation steps for a DRAM cell with RTDs, in accordance with an example embodiment.

FIG. 15 is a cross-sectional view of a completed example DRAM cell with two RTDs incorporated to latch the storage node voltage, in accordance with an example embodiment.

FIG. 16 is a cross-sectional view illustrating SiGe/Si stack epitaxy for an example 3D DRAM MST-RTD implementation, in accordance with an example embodiment.

FIG. 17 is a cross-sectional view illustrating SiGe/Si stack patterning and SiGe partial lateral recess for the example 3D DRAM MST-RTD implementation of FIG. 16, in accordance with an example embodiment.

FIG. 18 is an A-A′ cross-sectional view illustrating example MST/Si/MST/n-Si selective epitaxial stack formation for an RTD within a 3D DRAM structure, together with a plan view showing cross-section reference lines, in accordance with an example embodiment.

FIG. 19 is a B-B′ cross-sectional view of the 3D DRAM MST-RTD structure of FIG. 18, together with an enlarged detail view and band diagram of the MST/Si tunneling layer structure, in accordance with an example embodiment.

FIG. 20 is an A-A′ cross-sectional view showing an example 3D DRAM structure following completion of a baseline 3D DRAM process flow incorporating the MST-RTDs, in accordance with an example embodiment.

FIG. 21 is a cross-sectional view and circuit schematic of a completed example 3D DRAM cell with MST-RTD voltage latching elements, in accordance with an example embodiment.

FIG. 22A is a circuit schematic of an example MOBILE circuit including two RTDs for use with a gate-all-around (GAA) logic transistor, in accordance with an example embodiment.

FIG. 22B is a cross-sectional view of an example GAA FET and oxide barrier RTD device for MOBILE circuit implementation, in accordance with an example embodiment.

FIG. 23A is a cross-sectional view illustrating example PTS and N+ doping implantation steps for an oxide barrier GAA RTD process flow, in accordance with an example embodiment.

FIG. 23B is a cross-sectional view illustrating example MST diffusion blocking layer deposition and SiGe/Si nanosheet stack epitaxy in accordance with an example embodiment.

FIG. 24A is a cross-sectional view illustrating example nanosheet patterning and shallow trench isolation (STI) formation in accordance with an example embodiment.

FIG. 24B is a cross-sectional view illustrating example RTD block patterning and SiGe removal etch in accordance with an example embodiment.

FIG. 25A is a cross-sectional view illustrating example thermal oxidation and n+ poly-Si CVD steps for RTD formation in accordance with an example embodiment.

FIG. 25B is a cross-sectional view illustrating example RTD stack patterning in accordance with an example embodiment.

FIG. 26A is a cross-sectional view illustrating example RTD top layers removal in accordance with an example embodiment.

FIG. 26B is a cross-sectional view illustrating example sidewall oxidation and spacer formation in accordance with an example embodiment.

FIG. 27A is a cross-sectional view illustrating example oxide CVD and CMP planarization in accordance with an example embodiment.

FIG. 27B is a cross-sectional view of a completed example GAA FET and oxide barrier RTD device following regular GAA FET fabrication, in accordance with an example embodiment.

FIG. 28A is a cross-sectional view illustrating example PTS and N− doping implantation and GAA block patterning steps for an MST-RTD GAA process flow, in accordance with an example embodiment.

FIG. 28B is a cross-sectional view illustrating example selective SiGe/Si nanosheet stack epitaxy and nitride hard mask CVD in the GAA region, in accordance with an example embodiment.

FIG. 29A is a cross-sectional view illustrating example oxide CVD, CMP, GAA stack patterning, and STI formation steps, in accordance with an example embodiment.

FIG. 29B is a cross-sectional view illustrating example RTD region patterning in accordance with an example embodiment.

FIG. 30A is a cross-sectional view illustrating example MST/Si/MST/n-Si selective epitaxy and sidewall oxidation steps for RTD formation, in accordance with an example embodiment.

FIG. 30B is a cross-sectional view illustrating example oxide CVD and CMP planarization following MST-RTD epitaxy, in accordance with an example embodiment.

FIG. 31 is a cross-sectional view of a completed example GAA FET and MST-RTD device in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂.

Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ.

Alternately, the trapping of interstitials by MST layers may reduce the concentration of interstitial silicon proximate to the Si—SiO₂ interface, reducing the tendency to form sub-stoichiometric SiOₓ. Sub-stoichiometric SiOₓ at the Si—SiO₂ interface is known to exhibit inferior insulating properties relative to stoichiometric SiO₂. Reducing the amount of sub-stoichiometric SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

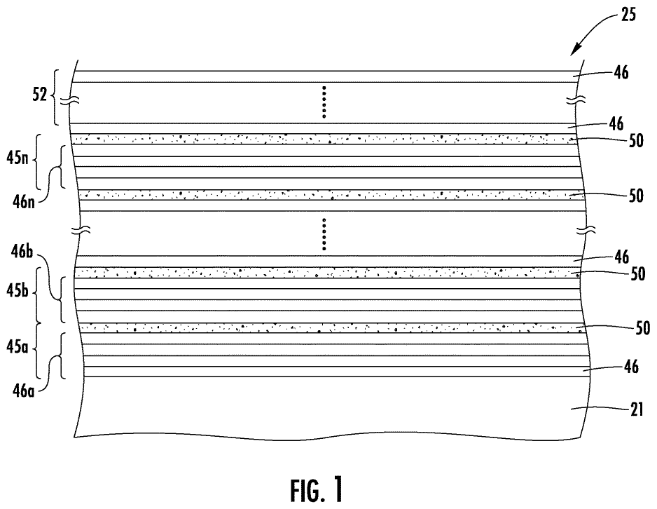

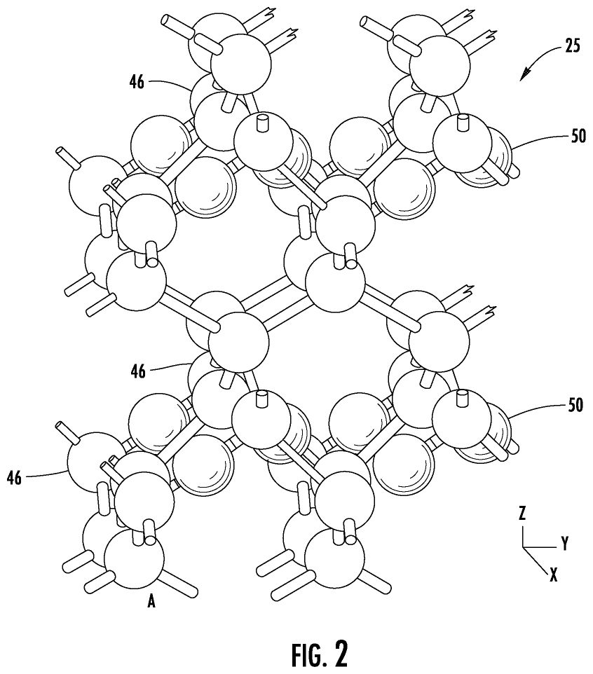

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base Semiconductor portions” it is meant that at least some semiconductor atoms from opposing base semiconductor portions 46a-46n are chemically bound together through the non-semiconductor monolayer 50 therebetween, as seen in FIG. 2.

Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably, between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used.

Accordingly, semiconductor devices incorporating the superlattice 25 in accordance with the invention may be readily adopted and implemented, as will be appreciated by those skilled in the art.

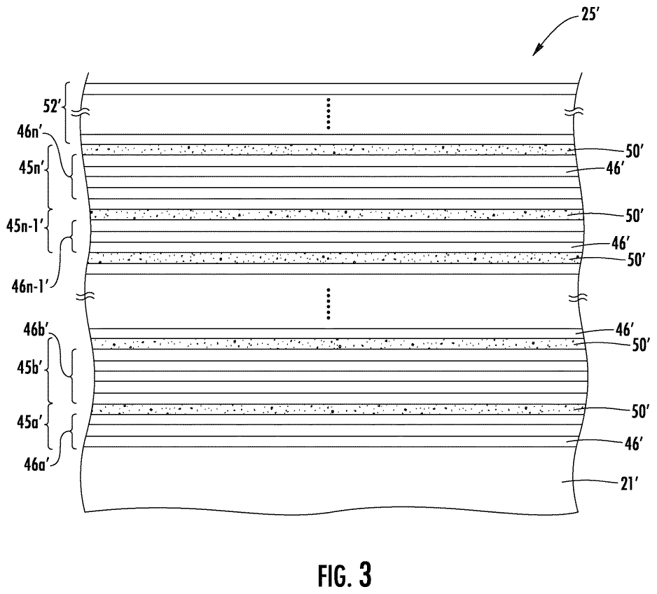

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

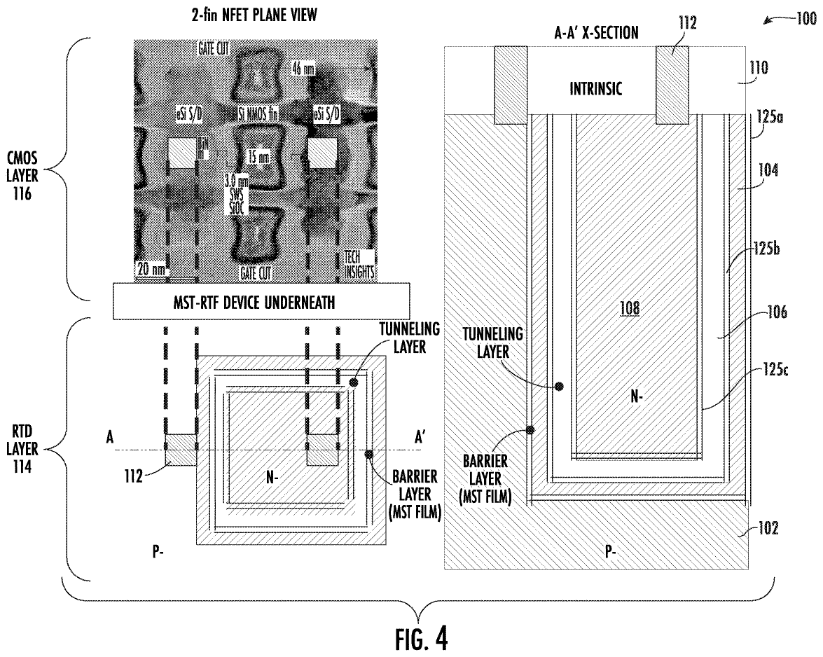

Turning now to FIGS. 4-31, various example device embodiments and fabrication approaches are described which incorporate resonant tunneling diodes (RTDs), some of which include MST layers as described above with reference to FIGS. 1-3. By way of background, an example semiconductor device configuration incorporating RTDs utilizing MST films is provided by the present Applicant in U.S. Pat. No. 10,170,604 to Mears et al., which is hereby incorporated herein in its entirety by reference. It will be appreciated by those skilled in the art that, while the embodiments described herein illustrate MST films as the barrier layer material in certain configurations, in some implementations an MST film in those positions may be replaced with a single non-semiconductor monolayer-for example, a single oxygen monolayer-to provide the barrier or tunneling characteristics described herein.

### Trench RTD and Mobile/CNN Circuits

Referring now to FIG. 4, an example trench RTD 100 configuration is shown. As illustrated in the plan view (left side of FIG. 4), a silicon substrate 102 defines an area reserved for an MST-RTD device, which is positioned within an RTD Layer 114 beneath a CMOS Layer 116. The CMOS Layer 116 includes conventional logic transistors, such as the illustrated 2-fin NFET, and the RTD layer 114 is positioned directly below the CMOS Layer without requiring any additional footprint in the CMOS layout. This vertical stacking arrangement enables area-efficient integration of the RTD with existing CMOS circuitry.

RTD contacts 112 (shown at the corners of the RTD region in the plan view) provide electrical connections to the underlying RTD device.

The right portion of FIG. 4 shows the A-A′ cross-sectional view through the trench RTD 100. The RTD 100 is formed within a trench etched into the silicon substrate 100. The RTD structure includes a central intrinsic silicon tunneling layer 106, surrounded sequentially by MST barrier layers 125a, 125b, 125c, which serve as the quantum tunneling barriers. The barrier layers are flanked by N− doped semiconductor regions 104, 108, and the outer extent of the trench region is defined by P− doped substrate material 102, 104. Overlying the RTD 100 is an intrinsic silicon layer 110 and the RTD contact electrodes 112. The barrier layers 125a-125c may include one or more MST superlattice films as described above with respect to FIGS. 1-3, providing enhanced quantum tunneling characteristics. In some implementations, the MST film barrier layers may be replaced with a single non-semiconductor monolayer such as a single oxygen monolayer. The trench geometry allows the effective RTD junction area to be increased by utilizing the trench sidewall, enabling higher current drive without increasing the footprint of the overlying CMOS circuitry.

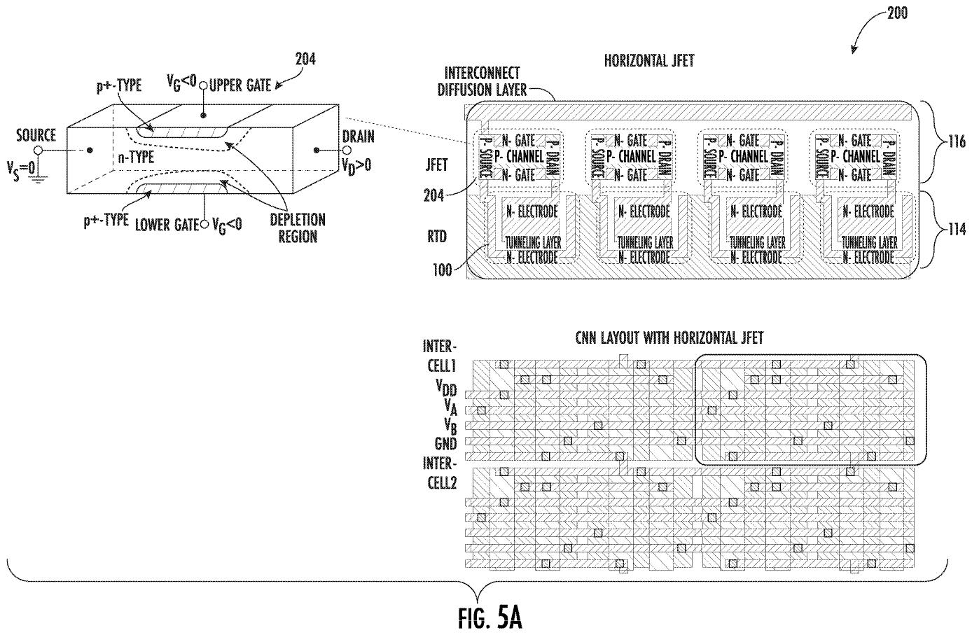

Referring now to FIG. 5A, an example layout of a MOBILE (monostable-bistable transition logic element) circuit 200 implemented using the trench RTD 100 of FIG. 4 is illustrated. A MOBILE circuit is realized by combining a JFET 204 (junction field-effect transistor) in series with one or more RTDs 100. FIG. 5A shows at upper left a schematic cross-section of an example horizontal JFET device 204, which includes p+-type upper and lower gate regions surrounding an n-type channel. The RTD layer 114 is stacked beneath the JFET layer, with an interconnect diffusion layer providing electrical coupling therebetween. Individual JFET cells 204 each include N-gate and P-channel regions, while each RTD cell 100 below includes N− electrodes flanking the central tunneling layer 106. The JFET and RTD structures may be fabricated using all-epitaxial silicon films and are compatible with placement beneath regular CMOS circuitry, with design rules independent from those of the logic FETs above.

The lower portion of FIG. 5A illustrates an example CNN (Cellular Neural Network) layout using these horizontal JFET 204 and RTD 100 MOBILE cells 200. The layout shows a regular array of MOBILE cells connected through inter-cell interconnects (Inter-cell1 and Inter-cell2), with power supply connections VDD, VA, VB, and GND running horizontally across the array. Each cell in the CNN array receives inputs from neighboring cells and provides outputs for analog or threshold logic computations, enabling fast image processing and neuromorphic operations. This configuration allows compact CNN circuits to be formed entirely beneath regular CMOS logic circuits.

FIG. 5B provides a circuit schematic showing in greater detail an example MOBILE circuit 200 formed by a single JFET 204 in series with a pair of anti-series connected RTDs 100, with the MOBILE element labeled in the upper right. A one-dimensional chain of such MOBILE cells is illustrated at center, with successive cells labeled Cell a−1, Cell a, and Cell a+1, connected in an inverter configuration in which each cell cross-couples its output state to adjacent cells and receives feedback from neighboring cells. This RTD/JFET MOBILE architecture is not limited to CNN applications but is also applicable to general Boolean and threshold logic circuit implementations.

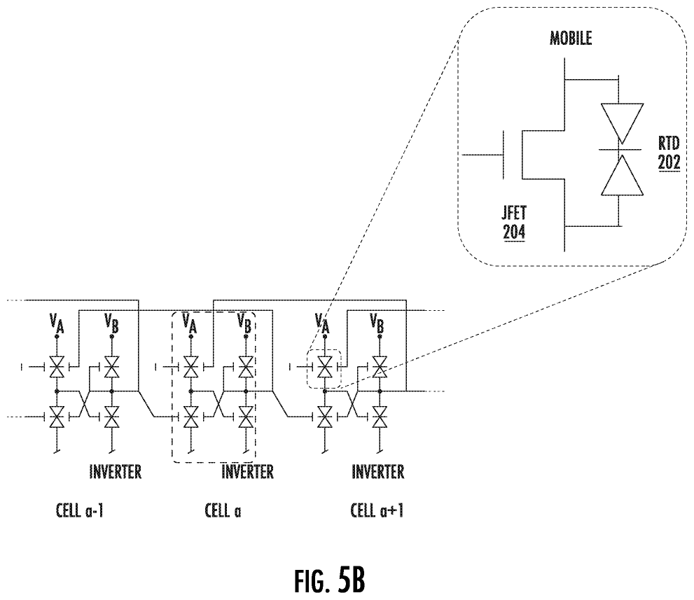

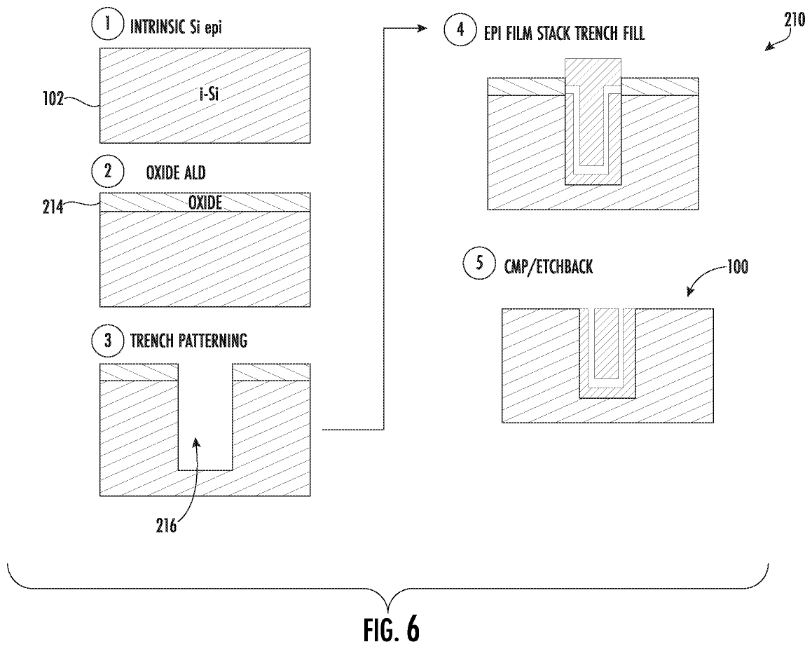

Referring now to FIG. 6, an example Epi damascene process 210 for fabricating the trench RTD and JFET structures of FIGS. 4-5B is illustrated. The process 210 proceeds in five steps. In step \textcircled{1}, an intrinsic silicon epitaxial layer (i-Si) 102 is grown on the substrate 100. In step \textcircled{2}, an oxide layer 214 is deposited by atomic layer deposition (ALD) over the i-Si layer. In step \textcircled{3}, the oxide 214 and i-Si 102 layers are patterned and etched to define the trench openings 216. In step \textcircled{4}, an epitaxial film stack-including the barrier and tunneling layers of the RTD is deposited to fill the defined trenches 216. In step \textcircled{5}, a chemical mechanical polishing (CMP) or etch-back step planarizes the surface and completes the trench-fill structure 100. This Epi damascene approach is compatible with subsequent conventional CMOS processing performed above the RTD layer.

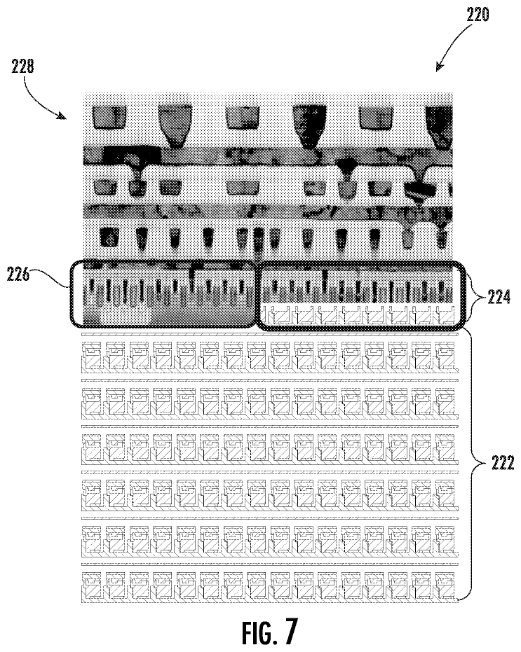

FIG. 7 illustrates an example 3D stacking approach for MOBILE circuits (JFET+MST RTD) beneath regular CMOS logic circuits. The overall 3D stack 220 includes multiple JFET+RTD MOBILE layers 222 stacked within the silicon substrate beneath the conventional logic CMOS layer 226, with interconnect layers 228 routing signals between them. Given that a silicon substrate is approximately 1 mm thick and each JFET+RTD MOBILE layer 222 is approximately 0.2 μm thick, approximately 5,000 such layers could potentially be stacked beneath the CMOS circuitry, for example. The annotated diagram indicates that the conventional logic CMOS layer 226 is augmented by the MOBILE-enhanced Logic CMOS layer 224 to provide logic system enhancement through threshold logic and multi-threshold logic, making this architecture well-suited for advanced processing applications such as neural networks and artificial intelligence.

### Planar RTD and RFSOI Integration

Referring now to FIG. 8, an example planar RTD structure 300 using conventional, non-exotic semiconductor materials is shown. The RTD 300 illustratively includes a bottom N+ poly-Si electrode 304 (approximately 100 nm thick), a first SiO₂ barrier layer 306 (approximately 1 mm thick) on the bottom electrode, a single-crystal Si tunneling layer 308 (approximately 2 nm thick) on the first SiO₂ barrier layer, a second SiO₂ barrier layer 310 (approximately 1 nm thick) on the tunneling layer, and a top N+ poly-Si electrode 312 (approximately 100 nm thick) on the second SiO₂ barrier layer. A base SiO₂ layer 302 (approximately 100 nm) underlies the bottom electrode, and a cap SiO₂ layer 314 (approximately 50 nm) overlies the top electrode, providing structural isolation.

Sidewall spacers 316 laterally isolate the RTD stack. The band diagram on the right side of FIG. 8 illustrates the double-barrier resonant tunneling potential profile, with the two SiO₂ (1.0 nm) barriers 306, 310 flanking the Si (2.0 nm) quantum well tunnel junction 308. The SiO₂ conduction band offset relative to Si is approximately 3.1 eV. This RTD structure advantageously employs only conventional silicon and silicon dioxide materials, rendering it fully compatible with standard CMOS processing without requiring compound semiconductor or other exotic materials.

FIG. 9 illustrates an example approach for integrating the RTD 300 of FIG. 8 into a standard RF silicon-on-insulator (RFSOI) process flow. A significant motivation for this integration is that conventional Si CMOS transistors are fundamentally limited to operating frequencies below approximately 300 GHz by the Johnson limit on the voltagexfrequency product, making them unable to support emerging THz wireless communication applications. RTD-based oscillators, by contrast, can operate well into the THz regime, and it has been shown that a peak-to-valley current ratio (PVR) of only approximately 2 is sufficient for THz oscillator applications-a threshold achievable with the SiO₂/Si/SiO₂RTD structure of FIG. 8. Prior THz RTD work has predominantly relied on compound semiconductor materials such as InGaAs/InAlAs, but the all-silicon RID of FIG. 8 provides a route to a Si-compatible THz signal source, addressable in a standard RFSOI flow.

The left portion of FIG. 9 describes a 10-step RTD module constituting a 3-mask process adder to the baseline RFSOI flow, including: (1) nitride patterning for the RTD region; (2) SOI thinning; (3) BOX undercut wet etch; (4) barrier oxide formation; (5) oxide/in-situ phosphorus-doped poly-Si CVD; (6) RTD stack patterning; (7) sidewall oxidation; (8) sidewall spacer formation; (9) top poly-Si/SOI removal patterning (for bottom electrode contact); and (10) oxide CVD for RTD device protection. The center portion of FIG. 9 provides a plan view RTD layout with three regions: A (top contact), B (RTD active region), and C (bottom contact). The right portion shows device cross-sections at the baseline, after step 6, and after step 10, each depicting the layered structure of oxide, SOI, poly-Si, and BOX from top to bottom. This integration approach adds THZ switching capability to an existing RFSOI platform with only three additional photomask steps.

### RTD-Enhanced DRAM (Oxide Barrier)

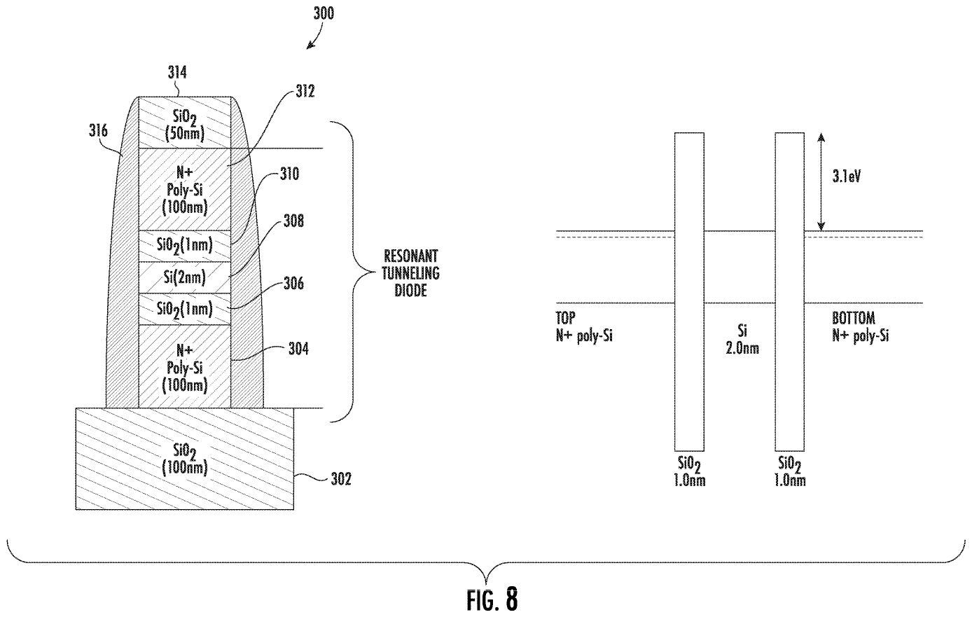

Referring now to FIGS. 10-15, example process steps for implementing oxide-barrier RTDs into a conventional 1-transistor/1-capacitor (1T1C) DRAM cell are described. Byway of background, conventional DRAM faces four major challenges: (1) memory access latency penalties associated with periodic refresh cycles; (2) energy overhead from refresh, which has been shown to account for more than 20% of total DRAM energy consumption, and which degrades system instruction-per-cycle (IPC) throughput by approximately 40% and memory access latency by approximately 25%; (3) row hammer vulnerability, in which repeated toggling of an aggressor word line causes charge pumping through interface traps that unintentionally releases stored charge in neighboring cells, representing a significant data security risk; and (4) random single-bit memory errors caused by retention time variation and process-induced defects, which grow more severe with technology scaling. By inserting two RTDs per cell such that the series RTD pair bistably latches the storage node voltage, this approach addresses all four of the above noted challenges. More particularly, the voltage latch enables complete elimination of refresh operations (converting the DRAM cell to an effectively static memory). The bistable latch helps eliminate row hammer vulnerability, since the latch actively restores charge displaced by the aggressor-induced charge pumping. Further, storage node charge leakage is suppressed because the latch continuously reinforces the storage node voltage rather than relying on passive charge retention.

Moreover, multi-bit-per-cell storage is enabled by exploiting the multiple current-peak I-V characteristic achievable through adjustment of the RTD tunneling layer thickness.

FIG. 10 shows the starting point for this RTD insertion process, including a plan view and A-A′ and B-B′ cross-sectional views of an example saddle FinFET DRAM cell, formed within silicon substrate 320. The plan view depicts word lines (WL) running horizontally and active regions running vertically, with the A-A′ cross-section taken along the word line direction and the B-B′ cross-section taken perpendicular thereto. The A-A′ cross-section shows alternating N+ source/drain regions 326, SiN spacers 327, and gate regions 324 forming the saddle fin geometry along the WL direction. The B-B′ cross-section shows N+ regions 326 separated by STI (shallow trench isolation) regions 322. This saddle FinFET structure serves as the baseline cell transistor into which the RTD structures are to be inserted.

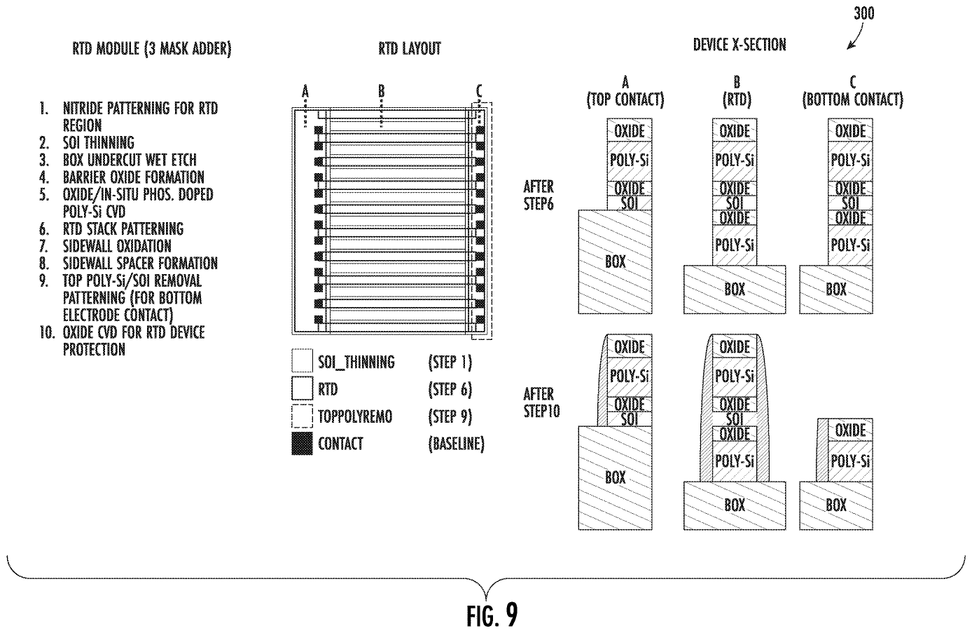

FIG. 11 illustrates a sequence of three process steps performed in the B-B′ cross-sectional direction for oxide barrier RTD insertion. In the first step (left cross-section), an oxide CVD is performed to form a BLC (bit line contact) blocking layer, followed by lithography/etch and selective epitaxial growth (SEG) of an MST 325/SiGe 326/Si 328 film stack in the RTD region, above the substrate 320 and adjacent to STI regions 322. The MST layer 325 in this step provides a significant technical advantage, in that it acts as a diffusion barrier that blocks upward diffusion of phosphorus dopant from the underlying N+ contact region into the Si tunneling layer during the subsequent epitaxial growth steps. Phosphorus contamination of the tunneling layer would degrade the sharpness of the RTD tunneling junction and reduce peak-to-valley current ratio. Yet, the MST layer suppresses this diffusion and thereby preserves the tunneling characteristics of the RTD.

In the second step (center cross-section), a sacrificial SiGe lateral etch removes the SiGe 326 from the Selectively grown film, leaving behind the Si 328 and MST 325 layers that define the RTD active region. In the third step (right cross-section), a radial oxidation (Rad Ox) is performed to form the SiO₂ barrier layers of the RTD, followed by an oxide CVD 332 and CVD of in-situ phosphorus-doped poly-Si 330 to form the N+ poly-Si electrode over the RTD tunneling stack. The completed structure shows the in-situ phosphorus-doped poly-Si electrode 330 surrounded by oxide 332, with N+ contact regions flanked by STI 322 above the substrate 320. It is noted that a thin (~1 nm) SiO₂ interface layer between the N+ poly-Si electrode and the underlying N+ silicon layer is not considered a yield-limiting defect in this structure.

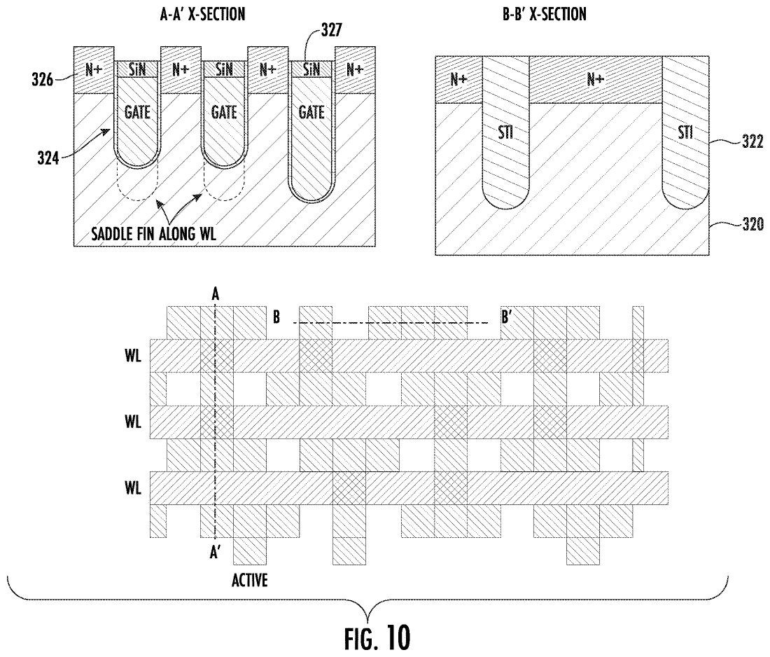

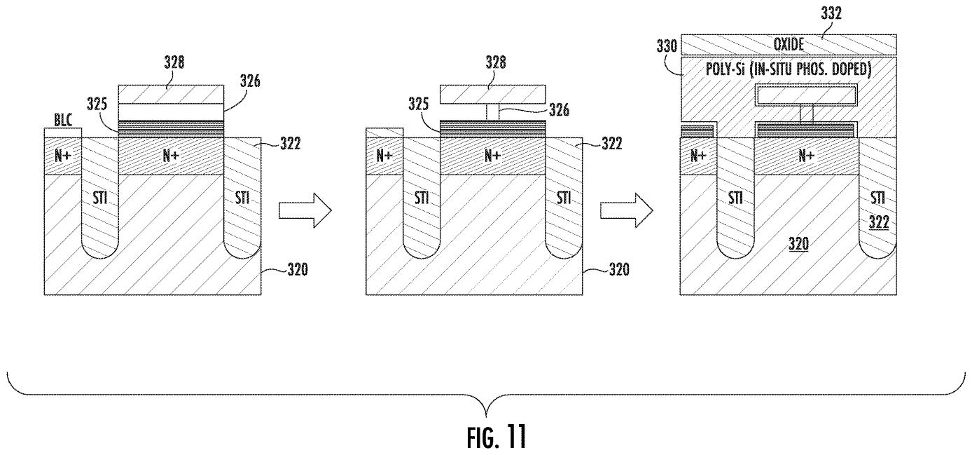

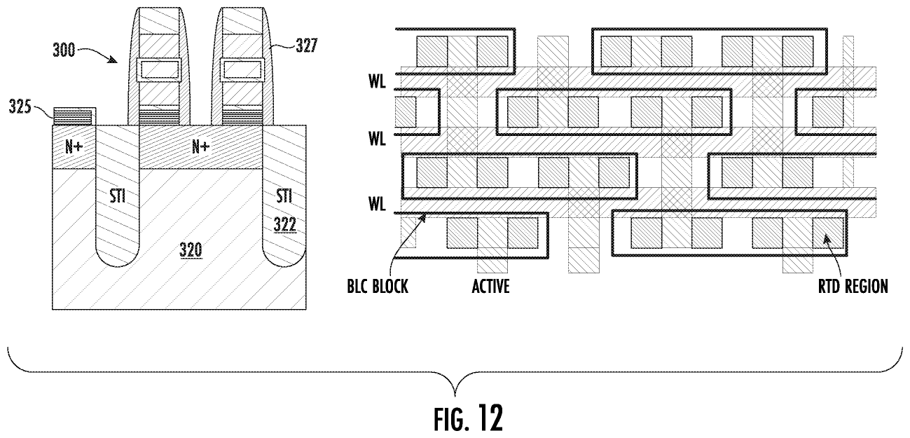

FIG. 12 shows an example cross-sectional view and plan view of the RTD region after RTD lithography/etch, radial oxidation (Rad Ox), and SiN sidewall spacer 327 formation. The left cross-section shows the N+ regions 326 and STI isolation 322 with the patterned RTD stack structures 300 protruding above. The plan view on the right identifies the BLC block region and the RTD region within the overall cell array, with word lines (WL) and active regions visible, providing context for the spatial relationship between the RTD structures 360 and the surrounding cell array.

FIG. 13 illustrates example oxide CVD/CMP and BL (bit line) and RTD Vref contact lithography/etch steps in both plan view and B-B′ cross-section. The plan view shows the cell array with the cross-section reference line, while the B-B′ cross-section at right shows the N+ regions 326 and STI 322 flanking the completed RTD 300, with sidewall oxide spacers visible.

Following oxide CVD and CMP planarization, contact openings are patterned and etched to define the bit line (BL) and RTD reference voltage (Vref) contacts adjacent to the RTD 300.

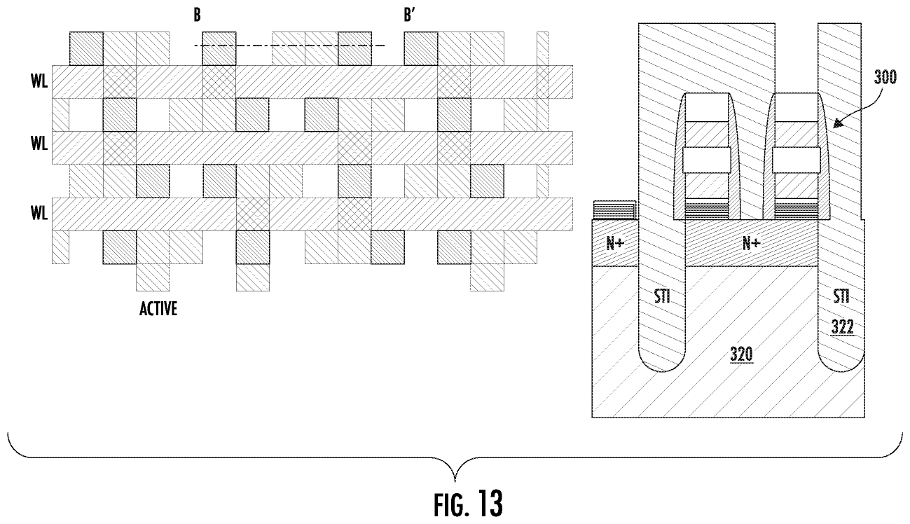

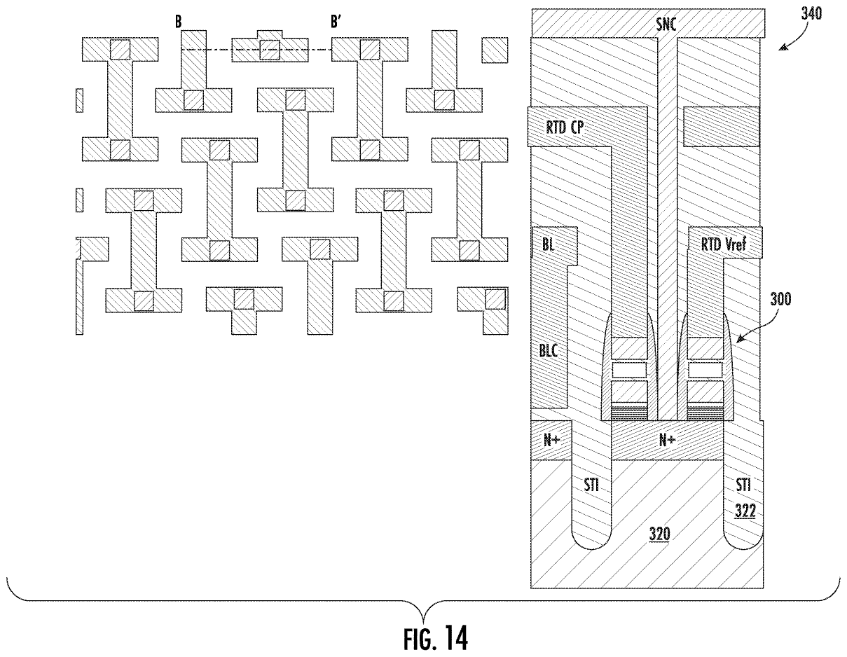

FIG. 14 shows subsequent process steps in both plan view and B-B′ cross-section: oxide CVD/CMP, storage node (SN) contact lithography/etch, and poly-Si CVD for the storage node poly fill. The B-B′ cross-section on the right of FIG. 14 illustrates the completed cell interconnect structure, with the BLC (bit line contact) providing access to one side of the cell transistor; the BL (bit line) running vertically above the BLC; the RTD CP (RTD cell plate) running horizontally to provide the upper electrode bias to both RTDs 300; the SNC (storage node contact) connecting upward to the storage capacitor; and the RTD Vref contact providing the reference bias to the lower electrode of the RTD pair. The plan view on the left shows the storage node contacts (red squares) within the cell array layout of the completed DRAM cell structure 340.

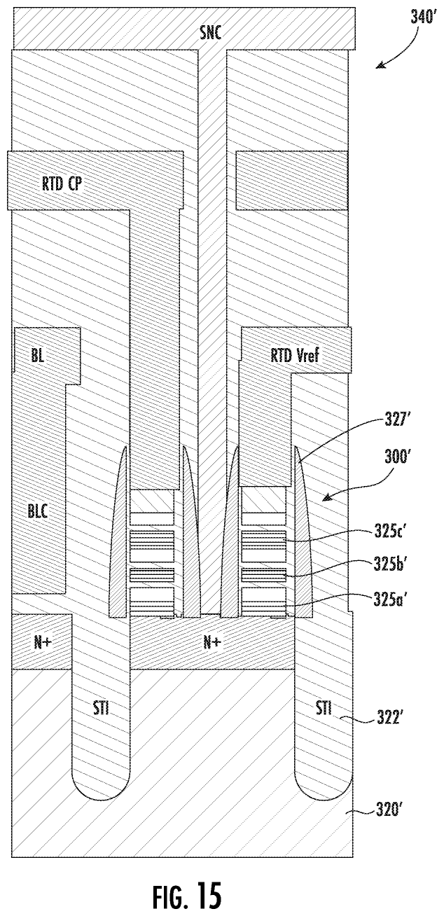

FIG. 15 provides a horizontal cross-sectional view of an alternative embodiment of an example DRAM cell 340′ with RTD 300′ implementation, showing the spatial relationship among the BLC, BL, RTD CP, SNC, and RTD Vref interconnect elements, together with the N+ transistor regions 326′ and STI isolation regions 322′ in the cell. In this configuration, MST barrier layers 325a', 325b', 325c′ serve as the tunneling barriers within the RTD structure 300. This completed structure represents a memory cell in which two RTDs are incorporated to bistably latch the storage node voltage.

With respect to the multi-bit-per-cell capability enabled by this structure, it is noted that a single RTD exhibits multiple current peaks in its I-V characteristic when the tunneling layer thickness is appropriately tuned-for example, a thinner tunneling layer produces a first current peak at a lower forward bias and a second peak at a higher bias, creating multiple stable operating points (multiple bistable latch states) corresponding to distinct stored voltage levels.

As an example, with a 1.0 nm SiO₂ barrier and an approximately 1.8 nm Si tunneling layer, two current peaks separated by approximately 60 mV have been projected, enabling 2 bits per cell (four states: (0,0), (0,1), (1,0), (1,1)). The process complexity increase for this oxide-barrier RTD DRAM integration is approximately four additional photomask steps relative to the baseline DRAM flow.

### 3D DRAM With MST-RTD

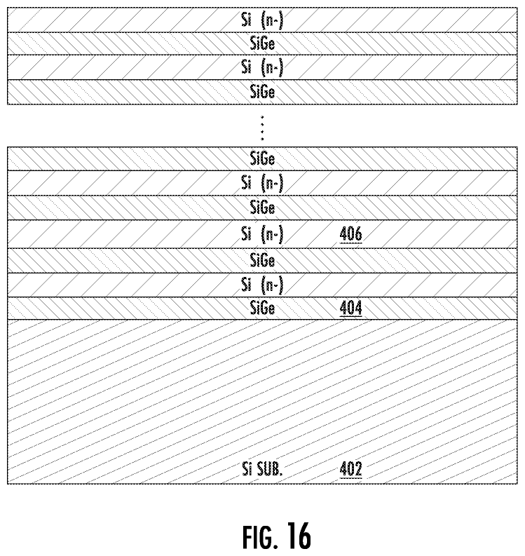

Referring now to FIGS. 16-21, an example process flow for implementing MST-barrier RTDs into a 3D DRAM architecture is described. This configuration addresses two related embodiments: first, the use of MST superlattice films as the RTD barrier layers in a conventional 1TIC DRAM cell (analogous to FIGS. 10-15 but with MST barriers replacing the thermal oxide barriers), and second, the application of MST-barrier RTDs to a 3D DRAM architecture. In both cases, the same four categories of DRAM improvement described above (namely refresh elimination with associated energy and latency benefits, complete row hammer immunity, storage node leakage elimination, and multi-bit-per-cell capability) apply.

An important additional advantage of the 3D DRAM MST-RTD integration shown in FIGS. 16-21 is process efficiency. More particularly, only one additional photomask step is required to integrate the MST-RTD into the 3D DRAM flow, and the resulting cell size increase is not significant because horizontal capacitors dominate the 3D DRAM cell area. The MST superlattice film provides the further advantage of acting as an inherent diffusion barrier, suppressing dopant redistribution during subsequent thermal steps and thereby preserving the tunneling junction integrity. As noted above, in some implementations, the MST film may be replaced with a single non-semiconductor monolayer, such as a single oxygen monolayer.

FIG. 16 illustrates the first step of this process, SiGe/Si stack epitaxy on a silicon substrate 402. The cross-sectional view shows multiple alternating layers of SiGe 404 and n-doped Si 406 grown above the Si substrate 402, forming the precursor nanosheet stack from which the 3D DRAM structure will be patterned. The n-doping in the Si layers 406 provides the electrode regions for the RTD.

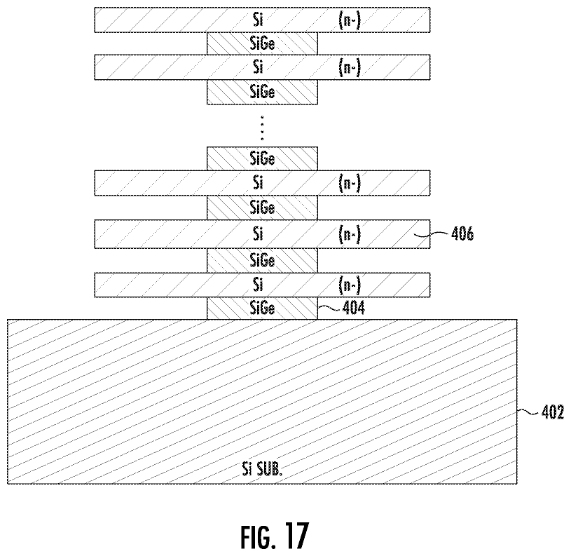

FIG. 17 shows the subsequent step of SiGe/Si stack patterning followed by SiGe 404 partial lateral recess, performed above the substrate 402. Following patterning and definition of the fins, the SiGe layers 404 are partially recessed laterally to create the beginning of the suspended Si nanosheet geometry. The n-doped Si layers 406 remain as partially suspended sheets supported by the remaining SiGe 404 at the fin edges, analogous to the nanosheet release step employed in GAA transistor fabrication.

FIG. 18 depicts the A-A′ cross-sectional view following selective epitaxial growth of an MST (5 nm)/Si (5 nm)/MST (5 nm)/n-Si (50 nm) stack within the laterally recessed regions created in the preceding step. The cross-section (left portion of FIG. 18) shows the RTD epitaxial stack within the patterned fin. MST barrier layers 425 (5 nm each) sandwich a thin Si tunneling layer 410 (5 nm), and the stack is capped by an n-Si electrode layer 408 (50 nm), all formed above the substrate 402 between SiGe support regions 404 and n-Si layers 406. The right side of FIG. 18 provides a plan view with A-A′ and B-B′ cross-section reference lines. The thin Si layer 410 between the two MST barrier layers 425 functions as the resonant quantum well, while the MST layers serve as the tunneling barriers and provide dopant diffusion blocking.

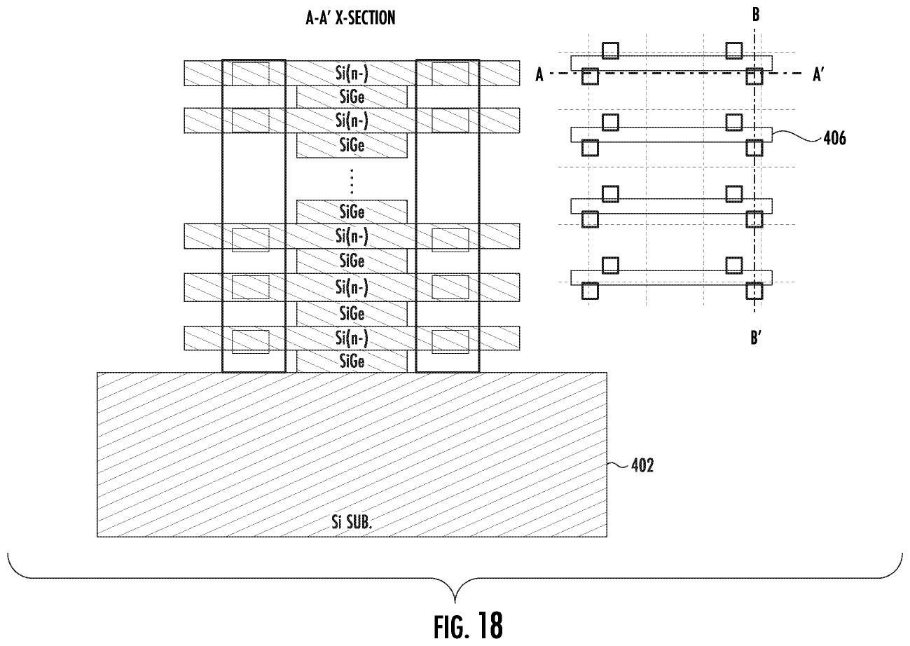

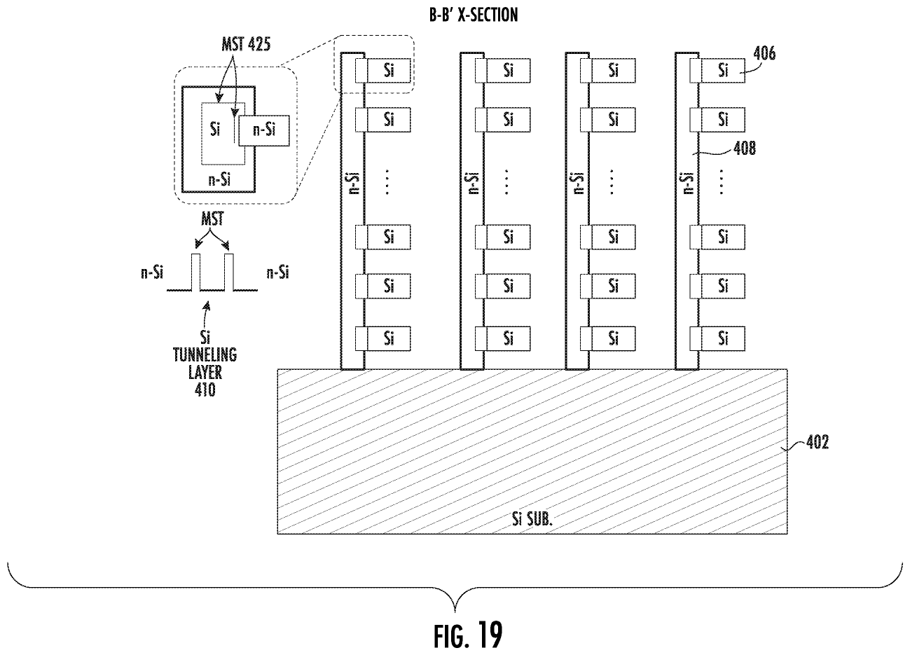

FIG. 19 provides the complementary B-B′ cross-sectional view of the 3D DRAM MST-RTD structure of FIG. 18. The right portion of FIG. 19 shows multiple column-like RTD structures extending upward from the Si substrate 402, each consisting of alternating Si 406 and n-Si 408 sections. The left portion of FIG. 19 provides an enlarged detail view and schematic band diagram illustrating the RTD tunneling structure, in which n-Si electrode regions 408 flank two MST barrier layers 425 sandwiching the central Si tunneling layer 410. The MST/Si/MST barrier-well-barrier structure thus provides the double-barrier quantum well necessary for resonant tunneling, using MST superlattice films as the barrier material in this 3D geometry.

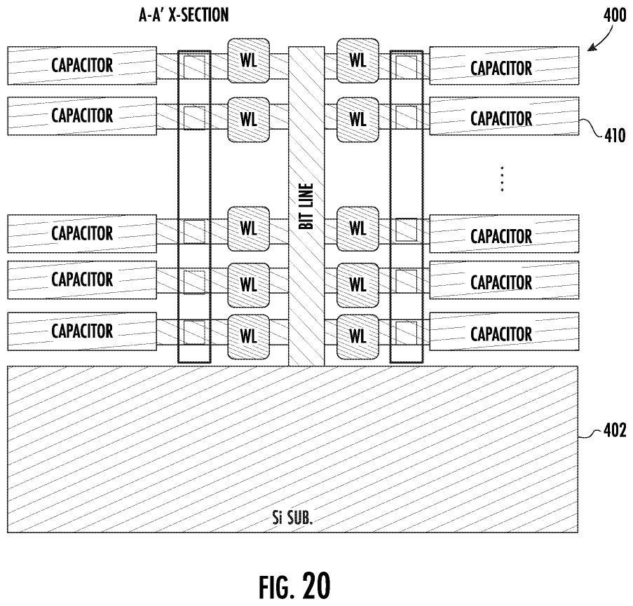

FIG. 20 shows the A-A′ cross-sectional view after completion of the baseline 3D DRAM process flow for the remaining fabrication steps. Following RTD insertion, the standard 3D DRAM fabrication modules are applied. The cross-section shows the completed 3D DRAM structure 400 with multiple stacked levels of word lines (WL) and horizontal capacitors on either side of a central vertical bit line (Bit line), all supported above the Si substrate 402. This cross-section illustrates how the RTD elements are embedded within the 3D DRAM structure at the individual cell level.

FIG. 21 provides both a structural cross-section and a circuit schematic of the completed 3D DRAM cell with MST-RTD voltage latching. The upper portion of FIG. 21 shows the layout cross-section of the 3D cell structure 400 with the A-A′ reference line, word lines (WL), VREF connections, GND connections, the bit line (BL), and horizontal capacitors on either side. The circuit schematic at the lower right of FIG. 21 shows how two RTDs 300 (RTD1 and RTD2) connected in anti-series between VREF and GND are coupled to the cell access transistor 412 (select transistor controlled by WL) and bit line (BL). The lower-left detail of FIG. 21 shows the MST-RTD cross-section with n-Si electrodes 408, MST barrier layers 425, and Si tunneling layer 410. The V_{REF}-RTD1-RTD2-GND series stack latches the storage node voltage bistably, providing SRAM-like data retention and helping eliminate DRAM refresh while enabling potential multi-bit-per-cell operation.

### GAA FET+ RTD Mobile (Oxide Barrier)

Referring now to FIGS. 22A-27B, an example implementation of an oxide-barrier RTD 300 integrated with a gate-all-around (GAA) transistor 502 at the same device level for MOBILE circuit 500 applications is described. FIG. 22A shows the circuit schematic for the example MOBILE 500 configuration. A single GAA FET 502 is connected in series with a pair of anti-series RTDs 300 (RTD1 and RTD2) between a clock signal (Clock) and the output node (OUT), with an input signal (IN) at the circuit input. This MOBILE circuit 500 exploits the negative differential resistance characteristic of the RTD pair to implement threshold logic and spike neural network operations.

FIG. 22B shows the corresponding cross-sectional device structure. The GAA FET 502 region (center) includes an alternating stack of HKMG (high-K metal gate) layers 512 and SiP source/drain regions 516 forming the nanosheet channels 514 in the GAA geometry, above the Si substrate 504 with a PTS (punch-through stop) doping region 508.

An MST diffusion blocking layer 525a is present at the base of the nanosheet stack in the GAA FET 502 region, serving to prevent up-diffusion of dopants from the PTS 508 and N+ doping regions 510 into the channel during subsequent thermal processing. The RTD 300 region (right) is laterally adjacent to the GAA FET 502 and shows N+ poly-Si bottom 304 and top 312 electrodes flanking the thin Si tunneling layer 308 (with SiO₂ barrier layers therebetween), with an MST diffusion blocking layer 525b below the RTD stack. The two regions are separated by STI 506, and an N+ doping region 510 provides the lower electrode contact for the RTD.

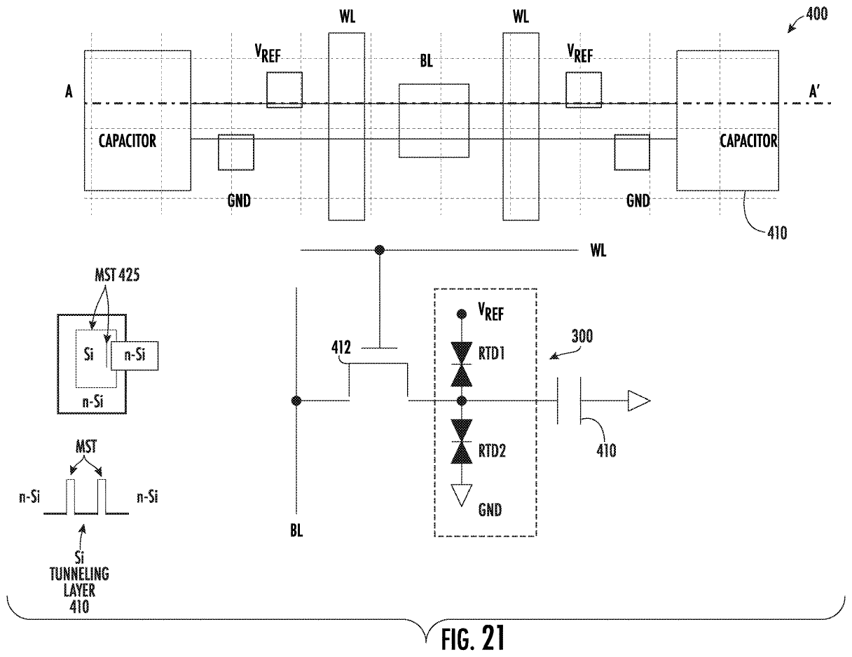

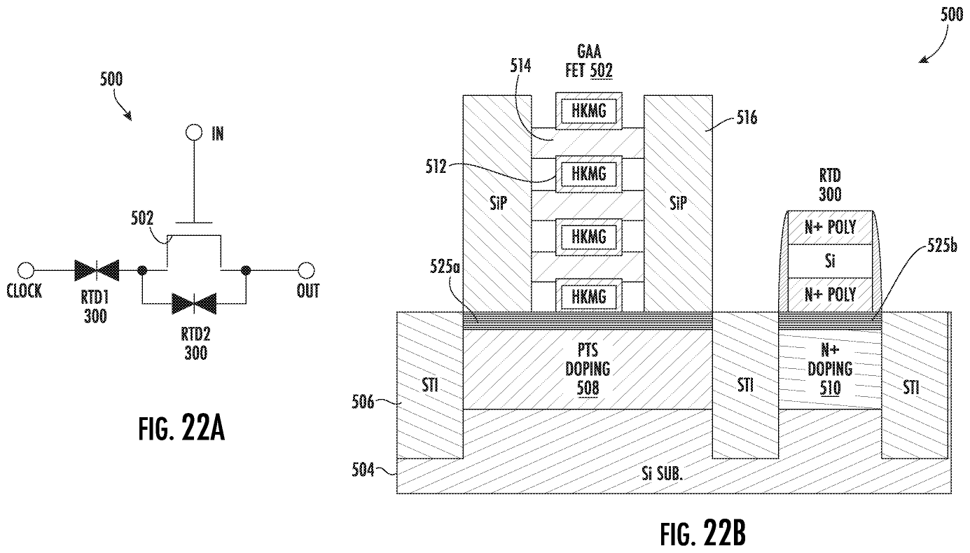

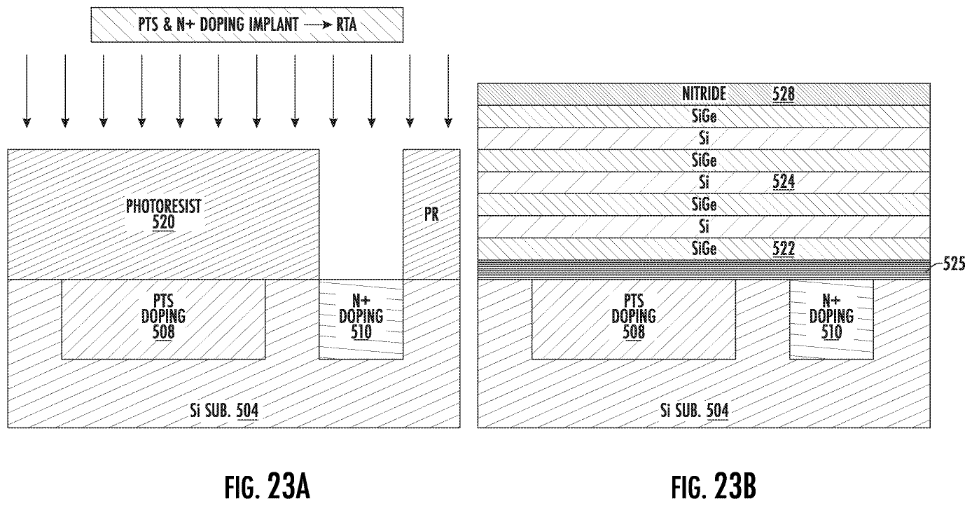

FIGS. 23A-27B illustrate an example five-stage process flow for fabricating the device of FIG. 22B. FIG. 23A depicts the initial substrate preparation, in which a silicon substrate 504 with a PTS doping region 508 and an N+ doping region 510 is patterned with photoresist 520, and PTS and N+ doping implantation followed by rapid thermal anneal (RTA) is performed to establish the well and electrode doping profiles. FIG. 23B shows the subsequent step where an MST diffusion blocking layer 525 is deposited over the substrate 504, followed by selective epitaxial growth of alternating SiGe 522/Si 524 layers forming the nanosheet precursor stack for the GAA FET region, with a nitride hard mask CVD layer 528 deposited above the stack. The MST layer 525, noted at the right of FIG. 23B, serves to block up-diffusion of the implanted dopants during the SiGe/Si stack epitaxy.

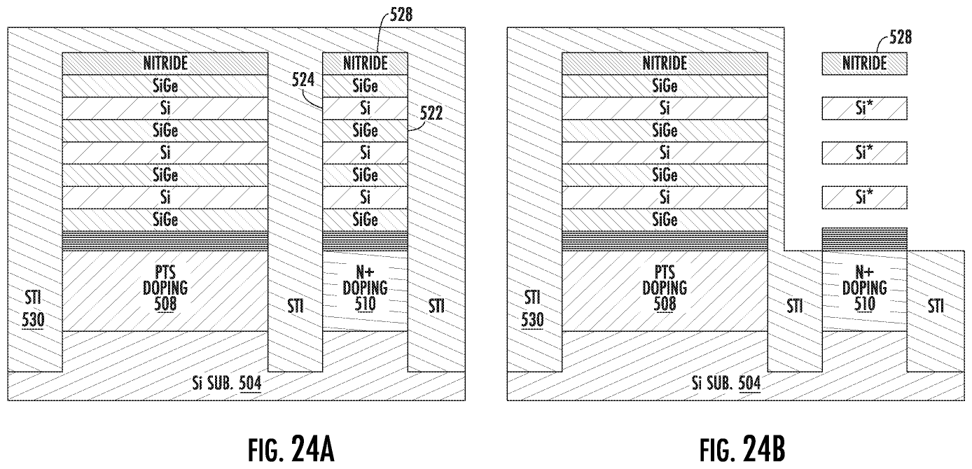

FIG. 24A shows the nanosheet patterning and STI 530 formation step. The SiGe 522/Si 524 stack is patterned into fins and STI is formed between and around the fins, with the patterned nanosheet stack visible in both the GAA FET region (left) and the N+ doping region 510 (right) for the RTD, all formed above the substrate 504 and separated by existing STI 506. FIG. 24B depicts RTD block patterning and SiGe removal etch, in which the SiGe sacrificial layers 522 are selectively removed from the RTD region, leaving behind suspended Si nanosheets 524 (labeled Si*) in the RTD region, while the GAA FET nanosheet stack remains intact. This creates a suspended nanosheet structure in the RTD region analogous to the channel-release step in GAA FET fabrication, with the suspended Si nanosheets 524 serving as the tunneling layer of the RTD.

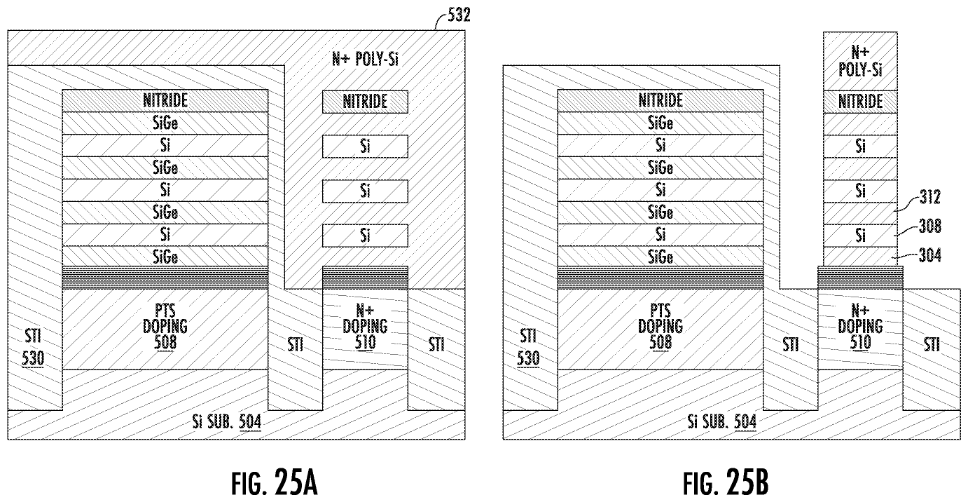

FIG. 25A illustrates thermal oxidation and n+ poly-Si CVD 532. Thermal oxidation is performed on the suspended Si nanosheets 524 in the RTD region to form the SiO₂ barrier layers of the RTD, then n+ poly-Si 532 is deposited by CVD over both the GAA FET nanosheet stack region and the RTD region, filling the RTD region with the top poly-Si electrode material while capping the GAA FET nanosheet stack. FIG. 25B shows the RTD stack patterning step, in which the n+ poly-Si 532 is lithographically patterned and etched to define the bottom electrode 304 and top electrode 312 dimensions in the N+ doping region 510, with the Si tunneling layer 308 sandwiched therebetween, while leaving the GAA FET nanosheet stack region undisturbed.

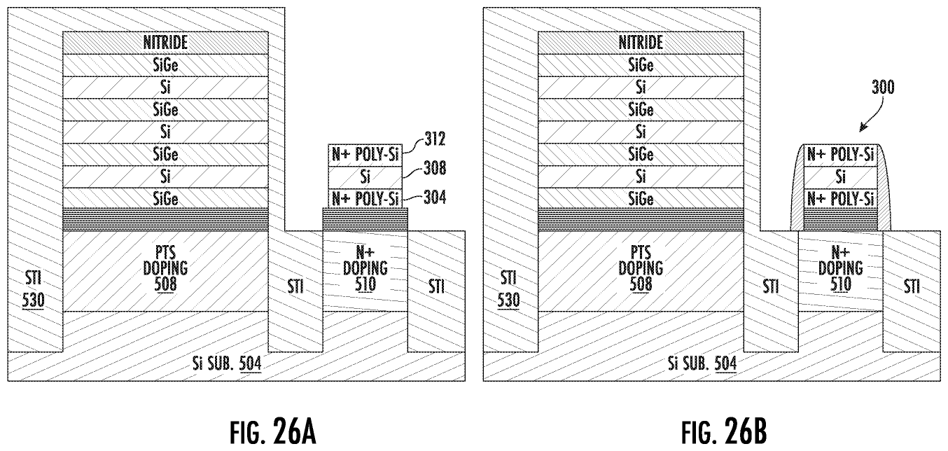

FIG. 26A shows the RTD top layers removal step. The upper excess poly-Si from the RTD stack region is selectively removed, exposing the thermally oxidized Si nanosheet tunneling structure 308 of the RTD 300 and leaving the patterned N+ poly-Si bottom 304 and top 312 electrode elements in the N+ doping region. FIG. 26B illustrates sidewall oxidation and spacer formation. Following RTD top layer removal, sidewall oxidation and oxide/nitride spacer 327 formation is performed, providing lateral isolation around the RTD device structure 300 and passivating the RTD sidewalls.

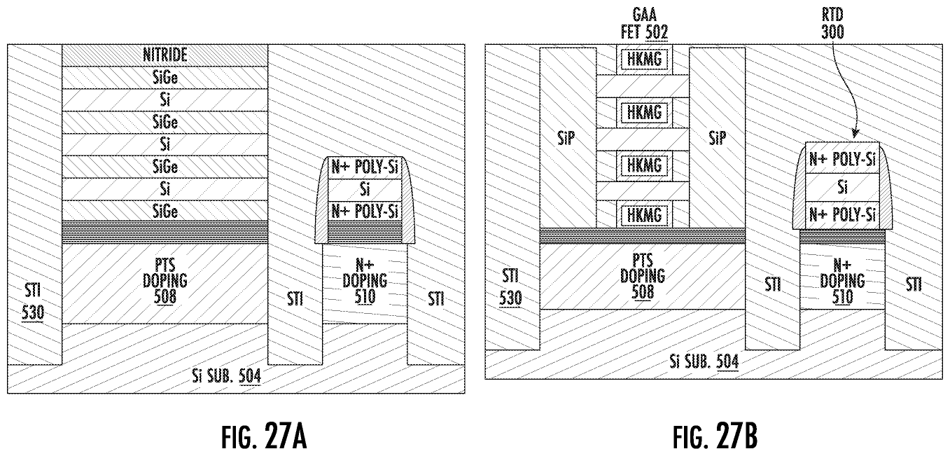

FIG. 27A shows the oxide CVD and CMP planarization step, in which an oxide is deposited to encapsulate the RTD structure 300 and the surface is planarized by CMP, preparing the substrate 504 for regular GAA FET 502 fabrication above the nanosheet stack region. FIG. 27B shows the cross-section of the finished example device. The GAA FET 502 (center) includes multiple HKMG gate stacks 512 surrounding Si nanosheets 514 with SiP source/drain regions 516, formed over the PTS doping region 508. The RTD 300 (right) includes N+ poly-Si top 312 and bottom 304 electrodes sandwiching the thermally oxidized Si nanosheet tunneling layer 308 (with SiO₂ barriers), formed in the N+ doping region 510 with an MST diffusion blocking layer 525 at the base. STI regions 506 separate the GAA FET and RTD regions.

### GAA FET+RTD Mobile (MST Barrier)

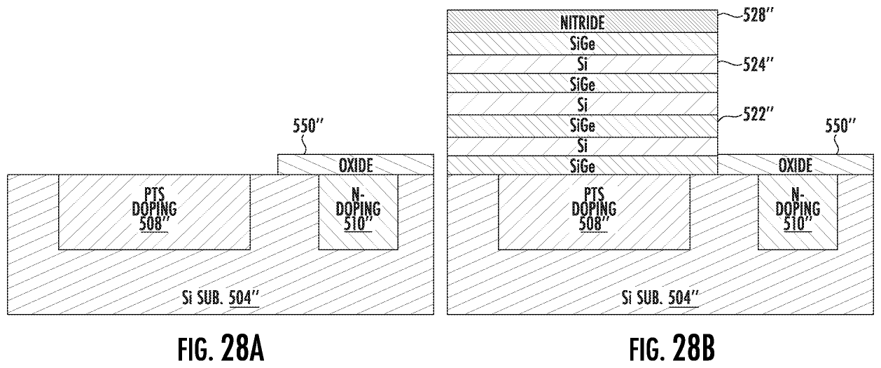

Referring now to FIGS. 28A-31, an alternative example implementation of the GAA FET+RTD MOBILE device is described in which MST superlattice films are used as the barrier layers of the RTD in place of thermal oxide. This approach follows a process flow analogous to that described above with reference to FIGS. 23A-27B, but uses MST/Si/MST selective epitaxy to form the RTD barrier and tunneling layers rather than thermal oxidation of the Si nanosheet, and employs N-rather than N+ doping in the RTD electrode regions.

FIG. 28A shows the initial substrate preparation step, in which the Si substrate 504″, with a PTS doping region 508″ (under the GAA FET region) and an N− doping region 510″ (under the RTD region), is processed by PTS and N− doping implantation, RTA, and GAA block patterning that defines an oxide mask 550″ protecting the RTD region while leaving the GAA FET region open for nanosheet epitaxy. The N− doping (rather than N+ as in the oxide-barrier approach) is used because the subsequent MST epitaxy provides the N+ electrode functionality in this embodiment. FIG. 28B depicts selective SiGe 522″/Si 524″ nanosheet stack epitaxy and nitride hard mask CVD 528″ in the GAA region. The SiGe/Si alternating layers are selectively grown only in the exposed GAA FET region (the oxide mask 530″ blocks growth in the RTD region), and a nitride hard mask 528″ is deposited above the stack.

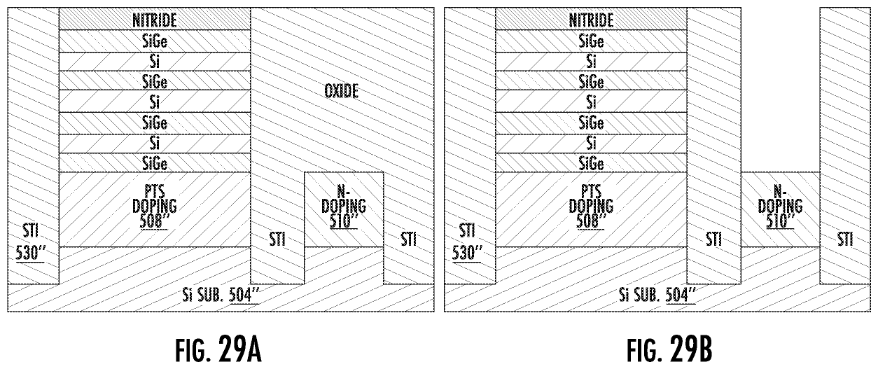

FIG. 29A illustrates oxide CVD, CMP, GAA stack patterning, and STI 506″ formation. After filling the structure with oxide and planarizing by CMP, the GAA nanosheet stack (SiGe 522″/Si 524″) is patterned into fins and STI 530″ is formed around both the GAA FET fin region (left fin stack) and the N− doping RTD region 510″ (right), all above the substrate 504″. An oxide cap 530″ remains over the RTD region at this stage. FIG. 29B shows the RTD region patterning step, in which the oxide cap 530″ over the RTD region is removed by lithography and etch, exposing the N− doped substrate 504″ surface in the RTD region for subsequent selective epitaxial deposition of the MST/Si/MST RTD barrier and tunneling stack.

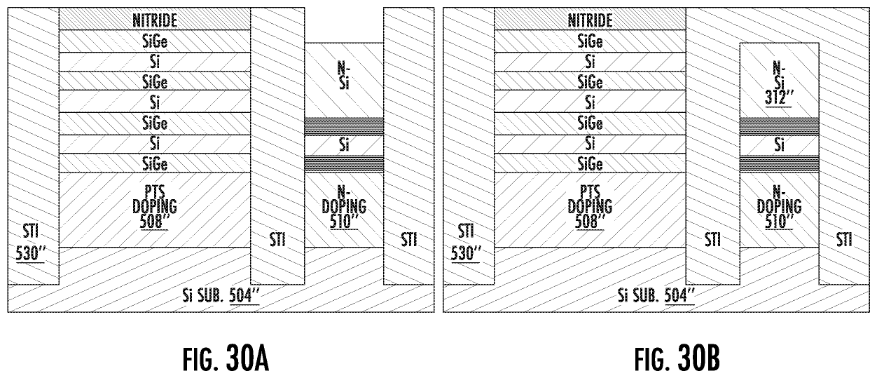

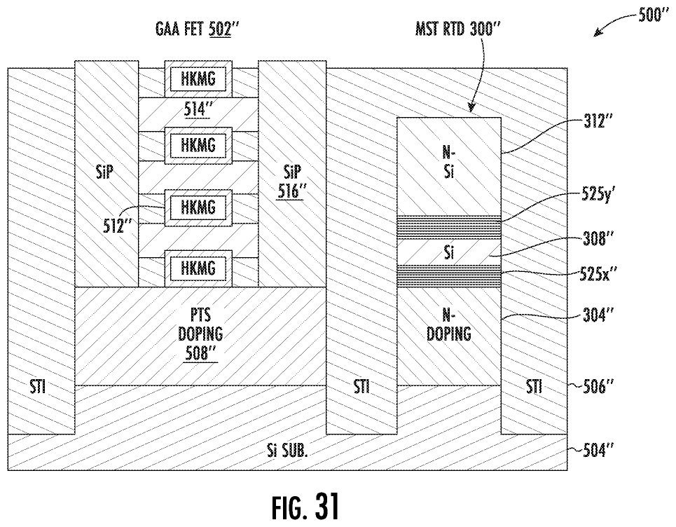

FIG. 30A illustrates the MST→Si→MST→n-Si selective epitaxy and sidewall oxidation steps performed in the RTD region. A first MST barrier layer 525x″ is selectively grown on the exposed N− doped surface 510″ in the RTD region, followed by a thin intrinsic Si tunneling layer 308″, a second MST barrier layer 525y“, and an n-Si electrode layer 312”. This selective epitaxy sequence produces the MST/Si/MST double-barrier tunneling junction 300″, with the MST superlattice films serving as the quantum tunneling barriers and the thin Si layer as the resonant quantum well. Sidewall oxidation is then performed to passivate the RTD structure sidewalls. FIG. 30B shows the subsequent oxide CVD and CMP step, which encapsulates and planarizes the MST-RTD structure 300″ in preparation for regular GAA FET fabrication.

FIG. 31 provides a cross-sectional view of the completed MST-RTD+GAA FET device 500″ following regular GAA FET fabrication. The GAA FET 502″ includes multiple stacked HKMG gate layers 512″ surrounding Si nanosheets 514″ with SiP source/drain regions 516″ on either side, formed above the PTS doping region 508″, in a structure analogous to that of FIG. 27B. The RTD 300″ (right) includes N-Si upper electrode 312″, first MST barrier layer 525x″, thin Si tunneling layer 308″, second MST barrier layer 525y″, and the N− doping electrode region 510″ below, with STI 506″ on either side providing lateral isolation. The MST barrier layers 525x“, 525y” in the RTD region provide the tunneling barrier functionality while also offering enhanced dopant diffusion blocking and potentially superior interface quality relative to a thermal oxide barrier. The completed structure integrates the MST-barrier RTD 300″ directly alongside the GAA FET 502″ at the same process level, enabling compact MOBILE circuit implementation for threshold logic and neuromorphic computing applications.

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that other modifications and embodiments are intended to be included within the scope of this disclosure.

1. A semiconductor device comprising:
a semiconductor substrate;
a resonant tunneling diode (RTD) above the semiconductor substrate and comprising
a first semiconductor electrode,
a first superlattice layer on the first semiconductor electrode,
a single crystal semiconductor tunneling layer on the first superlattice layer,
a second superlattice layer on the single crystal semiconductor tunneling layer, and
a second semiconductor electrode on the second superlattice layer; and
a gate all around (GAA) transistor on the semiconductor substrate laterally spaced apart from the RTD and electrically coupled thereto;
each of the first and second superlattice layers comprising a plurality of stacked groups of layers, each group of layers comprising a plurality of stacked base semiconductor monolayers defining a base semiconductor portion and at least one non-semiconductor monolayer constrained within a crystal lattice of adjacent base semiconductor portions.

2. The semiconductor device of claim 1 wherein the GAA transistor comprises an alternating stack of gate layers and semiconductor nanosheet layers, and source and drain regions on opposite sides of the stack defining a channel through the semiconductor nanosheet layers.

3. The semiconductor device of claim 2 wherein the gate layers comprise high K metal gate (HKMG) layers.

4. The semiconductor device of claim 1 wherein the first and second semiconductors electrodes comprise a single crystal semiconductor material.

5. The semiconductor device of claim 4 wherein the first and second semiconductor electrodes comprises single crystal silicon.

6. The semiconductor device of claim 1 further comprising punch through stop (PTS) dopant region in the semiconductor substrate beneath the GAA transistor.

7. The semiconductor device of claim 1 further comprising a shallow trench isolation (STI) region between the RTD and GAA transistor.

8. The semiconductor device of claim 1 wherein the base semiconductor comprises silicon.

9. The semiconductor device of claim 1 wherein the at least one non-semiconductor monolayer comprises oxygen.

10. A semiconductor device comprising:
a silicon substrate;
a resonant tunneling diode (RTD) above the silicon substrate and comprising
a first silicon electrode,
a first superlattice layer on the first silicon electrode,
a single crystal silicon tunneling layer on the first superlattice layer,
a second superlattice layer on the single crystal silicon tunneling layer, and
a second silicon electrode on the second superlattice layer; and
a gate all around (GAA) transistor on the silicon substrate laterally spaced apart from the RTD and electrically coupled thereto;
each of the first and second superlattice layers comprising a plurality of stacked groups of layers, each group of layers comprising a plurality of stacked base silicon monolayers defining a base silicon portion and at least one oxygen monolayer constrained within a crystal lattice of adjacent base silicon portions.

11. The semiconductor device of claim 10 wherein the GAA transistor comprises an alternating stack of gate layers and silicon nanosheet layers, and silicon source and drain regions on opposite sides of the stack defining a channel through the semiconductor nanosheet layers.

12. The semiconductor device of claim 11 wherein the gate layers comprise high K metal gate (HKMG) layers.

13. The semiconductor device of claim 10 wherein the first and second silicon electrodes comprise a single crystal silicon.

14. The semiconductor device of claim 10 further comprising punch through stop (PTS) dopant region in the silicon substrate beneath the GAA transistor.

15. The semiconductor device of claim 10 further comprising a shallow trench isolation (STI) region between the RTD and GAA transistor.

16. A method for making a semiconductor device comprising:
forming a resonant tunneling diode (RTD) above a semiconductor substrate by
forming a first superlattice layer on a first semiconductor electrode,
forming a single crystal semiconductor tunneling layer on the first superlattice layer,
forming a second superlattice layer on the single crystal semiconductor tunneling layer, and
forming a second semiconductor electrode on the second superlattice layer; and
forming a gate all around (GAA) transistor on the semiconductor substrate laterally spaced apart from the RTD and electrically coupled thereto;
each of the first and second superlattice layers comprising a plurality of stacked groups of layers, each group of layers comprising a plurality of stacked base semiconductor monolayers defining a base semiconductor portion and at least one non-semiconductor monolayer constrained within a crystal lattice of adjacent base semiconductor portions.

17. The method of claim 16 wherein forming the GAA transistor comprises forming an alternating stack of gate layers and semiconductor nanosheet layers, and forming source and drain regions on opposite sides of the stack defining a channel through the semiconductor nanosheet layers.

18. The method of claim 17 wherein the gate layers comprise high K metal gate (HKMG) layers.

19. The method of claim 16 wherein the first and second semiconductors electrodes comprise a single crystal semiconductor material.

20. The method of claim 16 further comprising forming a punch through stop (PTS) dopant region in the semiconductor substrate beneath the GAA transistor.

21. The method of claim 16 further comprising forming a shallow trench isolation (STI) region between the RTD and GAA transistor.

22. The method of claim 16 wherein the base semiconductor comprises silicon, and the at least one non-semiconductor monolayer comprises oxygen.
